(19) United States
(12) Patent Application Publication
(10) Pub. No.: US 2024/0332147 A1
(43) Pub. Date: Oct. 3, 2024

(54) SEMICONDUCTOR APPARATUS AND METHOD OF MANUFACTURING THE SAME

(71) Applicant: Mitsubishi Electric Corporation, Tokyo (JP)

(72) Inventor: Yusuke ISHIYAMA, Tokyo (JP)

(73) Assignee: Mitsubishi Electric Corporation, Tokyo (JP)

(21) Appl. No.: 18/610,683

(22) Filed: Mar. 20, 2024

(30) Foreign Application Priority Data
Mar. 30, 2023 (JP) 2023-055620

(51) Int. Cl. H01L 23/498; H01L 21/48; H01L 23/373

(52) U.S. Cl. CPC H01L 23/49811; H01L 21/4853; H01L 23/3735

(57) ABSTRACT

A semiconductor apparatus includes an insulating substrate and an electrode. The insulating substrate includes an insulating layer including a first main surface, and a circuit pattern. The circuit pattern is disposed on the first main surface and includes a first portion. The electrode includes a second portion bonded to the first portion. Bonding between the first portion and the second portion is ultrasonic bonding. One of the first portion and the second portion is fitted in the other of the first portion and the second portion.

### CROSS REFERENCE TO RELATED APPLICATIONS

This nonprovisional application is based on Japanese Patent Application No. 2023-055620 filed on Mar. 30, 2023 with the Japan Patent Office, the entire contents of which are hereby incorporated by reference.

### BACKGROUND OF THE INVENTION

### Field of the Invention

The present disclosure relates to a semiconductor apparatus and a method of manufacturing the same.

### Description of the Background Art

Japanese Patent Laying-Open No. 2022-37739 discloses a semiconductor apparatus including a laminated substrate and a connection terminal. The laminated substrate includes an insulating board and a heat dissipation board laminated on a rear surface of the insulating board. The insulating substrate has a recess for positioning the connection terminal. When the connection terminal is ultrasonically bonded to the insulating board, the connection terminal is positioned by the recess so that misalignment of the connection terminal relative to the insulating board is suppressed.

### SUMMARY OF THE INVENTION

In the semiconductor apparatus disclosed in Japanese Patent Laying-Open No. 2022-37739, the thickness of the insulating board is reduced at the recess, causing degradation in insulating performance of the insulating board. The present disclosure is made to solve the aforementioned problem, and an object of the present disclosure is to provide a semiconductor apparatus and a method of manufacturing the same in which the electrical insulation of an insulating layer is ensured while misalignment of an electrode relative to a circuit pattern is suppressed when the electrode is ultrasonically bonded to the circuit pattern.

A semiconductor apparatus according to the present disclosure includes an insulating substrate and an electrode. The insulating substrate includes an insulating layer including a first main surface, and a circuit pattern. The circuit pattern is disposed on the first main surface and includes a first portion. The electrode includes a second portion bonded to the first portion. Bonding between the first portion and the second portion is ultrasonic bonding. One of the first portion and the second portion is fitted in the other of the first portion and the second portion.

A method of manufacturing a semiconductor apparatus according to the present disclosure includes preparing an insulating substrate and an electrode. The insulating substrate includes an insulating layer and a circuit pattern. The circuit pattern is disposed on the insulating layer and includes a first portion. The electrode includes a second portion. The method of a semiconductor apparatus in the present embodiment includes fitting one of the first portion and the second portion into the other of the first portion and the second portion, and ultrasonically bonding the first portion and the second portion.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partially-enlarged schematic plan view of a semiconductor apparatus according to a first embodiment.

FIG. 2 is a partially-enlarged schematic front view of the semiconductor apparatus according to the first embodiment as viewed from direction II shown in FIG. 1.

FIG. 3 is a partially-enlarged schematic side view of the semiconductor apparatus according to the first embodiment as viewed from direction III shown in FIG. 1.

FIG. 4 is a partially-enlarged schematic cross-sectional view of the semiconductor apparatus according to the first embodiment along line IV-IV shown in FIG. 1.

FIG. 5 is a flowchart of a method of manufacturing a semiconductor apparatus according to the first embodiment.

FIG. 6 is a partially-enlarged schematic cross-sectional view showing an ultrasonic bonding process in the method of manufacturing a semiconductor apparatus according to the first embodiment.

FIG. 7 is a partially-enlarged schematic plan view of a semiconductor apparatus according to a second embodiment.

FIG. 8 is a partially-enlarged schematic cross-sectional view of the semiconductor apparatus according to the second embodiment along line VIII-VIII shown in FIG. 7.

FIG. 9 is a partially-enlarged schematic cross-sectional view of a semiconductor apparatus according to a modification of the second embodiment.

FIG. 10 is a partially-enlarged schematic plan view of a semiconductor apparatus according to a third embodiment.

FIG. 11 is a partially-enlarged schematic cross-sectional view of the semiconductor apparatus according to the third embodiment along line XI-XI shown in FIG. 10.

FIG. 12 is a partially-enlarged schematic cross-sectional view of a semiconductor apparatus according to a modification of the third embodiment.

### DESCRIPTION OF THE PREFERRED EMBODIMENTS

Embodiments of the present disclosure will be described below. The same components are denoted by the same reference numerals and a description thereof will not be repeated.

### First Embodiment

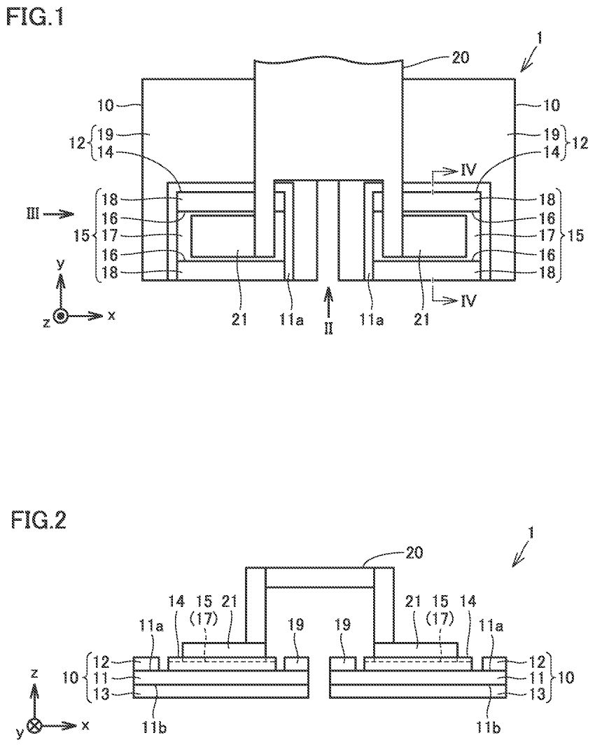

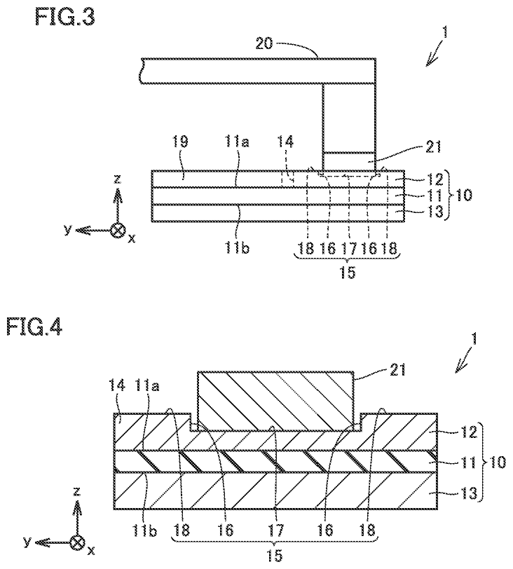

Referring to FIG. 1 to FIG. 4, a semiconductor apparatus 1 in a first embodiment will be described. Semiconductor apparatus 1 includes an insulating substrate 10, an electrode 20, and a semiconductor device (not shown) placed on insulating substrate 10. The semiconductor device is, for example, a power semiconductor device such as a metal oxide semiconductor field-effect transistor (MOSFET) or an insulated gate bipolar transistor (IGBT). Semiconductor apparatus 1 is, for example, a power semiconductor apparatus.

Insulating substrate 10 includes an insulating layer 11, a circuit pattern 12, and a heat dissipation plate 13.

Insulating layer 11 includes a first main surface 11a and a second main surface 11b opposite to first main surface 11a. First main surface 11a and second main surface 11b each extend in an x direction and a y direction perpendicular to the x direction. The normal direction to first main surface 11a and the normal direction to second main surface 11b are each a z direction perpendicular to the x direction and the y direction. Insulating layer 11 is formed of, for example, ceramic such as aluminum nitride (AlN), aluminum oxide (Al₂O₃), or silicon nitride (Si₃N₄), or an insulating resin such as epoxy resin. A filler such as silica, alumina, or boron nitride (BN) may be dispersed in insulating layer 11 of resin.

Circuit pattern 12 is disposed on first main surface 11a of insulating layer 11. Circuit pattern 12 is, for example, brazed to insulating layer 11. Circuit pattern 12 is formed of a metal such as copper (Cu) or aluminum (Al). Circuit pattern 12 includes a portion 14 and a portion 19. Portion 19 is spaced apart from portion 14 and electrically insulated from portion 14. Portions 14 and 19 are each a conductive pattern.

Heat dissipation plate 13 is disposed on second main surface 11b of insulating layer 11. Heat dissipation plate 13 is formed of, for example, a metal such as Cu or Al. Heat dissipation plate 13 dissipates heat generated in semiconductor apparatus 1 to the outside of semiconductor apparatus 1.

Electrode 20 is formed of a metal such as Cu. Electrode 20 includes a portion 21. Portion 21 is, for example, an end portion of electrode 20. Portion 21 of electrode 20 is ultrasonically bonded to portion 14 of circuit pattern 12.

One of portion 14 of circuit pattern 12 and portion 21 of electrode 20 is fitted in the other of portion 14 of circuit pattern 12 and portion 21 of electrode 20. In the present embodiment, portion 14 of circuit pattern 12 has a recess 15. Recess 15 is formed, for example, by etching with chemicals. Portion 21 of electrode 20 is fitted in recess 15.

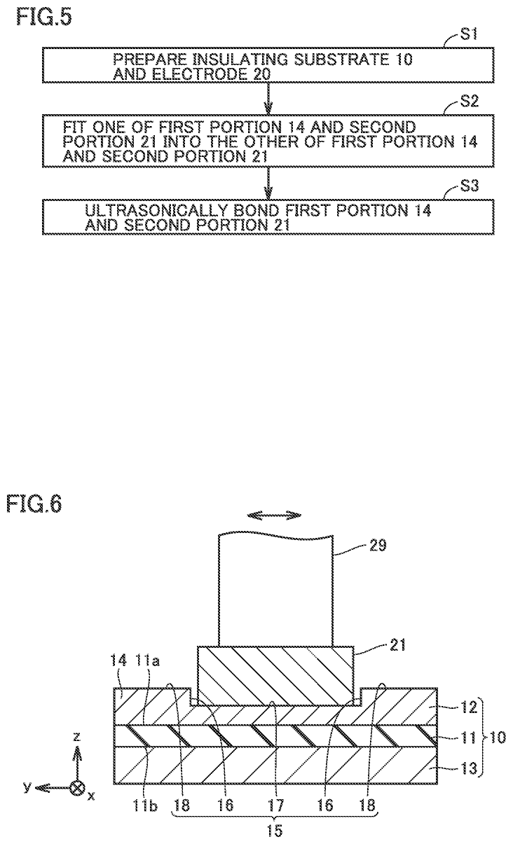

Recess 15 includes a step 16, a lower stepped surface 17, and an upper stepped surface 18. Step 16 is connected to lower stepped surface 17 and upper stepped surface 18. As shown in FIG. 1 and FIG. 4, in a planar view of first main surface 11a of insulating layer 11, a pair of steps 16 are opposed to both side surfaces of portion 21. Portion 21 of electrode 20 is ultrasonically bonded to lower stepped surface 17 of recess 15. As shown in FIG. 6, in a planar view of first main surface 11a of insulating layer 11, step 16 of recess 15 extends in a direction (for example, z direction) perpendicular to the direction (y direction) of ultrasonic vibration applied for ultrasonic bonding between portion 14 of circuit pattern 12 and portion 21 of the electrode. In the present description, the direction perpendicular to the direction of ultrasonic vibration means the direction at an angle of 75° to 105° relative to the direction of ultrasonic vibration.

Referring to FIG. 5 and FIG. 6, a method of manufacturing semiconductor apparatus 1 in the present embodiment will be described.

The method of manufacturing semiconductor apparatus 1 in the present embodiment includes preparing insulating substrate 10 and electrode 20 (step S1). Insulating substrate 10 includes insulating layer 11 and circuit pattern 12. Circuit pattern 12 includes portions 14 and 19. Portion 14 has recess 15. Electrode 20 includes portion 21.

The method of manufacturing semiconductor apparatus 1 in the present embodiment includes fitting one of portion 14 of circuit pattern 12 and portion 21 of electrode 20 into the other of portion 14 of circuit pattern 12 and portion 21 of electrode 20 (step S2). In the present embodiment, portion 21 of electrode 20 is fitted into recess 15 provided in portion 14 of circuit pattern 12.

The method of manufacturing semiconductor apparatus 1 in the present embodiment includes ultrasonically bonding portion 14 of circuit pattern 12 and portion 21 of electrode 20 (step S3). Portion 21 of electrode 20 is ultrasonically bonded to portion 14 of circuit pattern 12. Specifically, portion 21 of electrode 20 is ultrasonically bonded to lower stepped surface 17 of recess 15. Portion 21 of electrode 20 is fitted in recess 15 provided in portion 14 of circuit pattern 12. A pair of steps 16 are opposed to both side surfaces of portion 21 to restrict the movement of electrode 20. Thus, during the ultrasonic bonding process (step S3), the movement of electrode 20 relative to circuit pattern 12 is restricted, so that misalignment of electrode 20 relative to circuit pattern 12 is suppressed. Furthermore, since the thickness of a part of insulating layer 11 is not reduced in order to suppress misalignment of electrode 20 relative to circuit pattern 12, the electrical insulation of insulating layer 11 is ensured.

The effects of semiconductor apparatus 1 and the method of manufacturing the same in the present embodiment will be described.

Semiconductor apparatus 1 in the present embodiment includes insulating substrate 10 and electrode 20. Insulating substrate 10 includes insulating layer 11 and circuit pattern 12. Insulating layer 11 includes first main surface 11a. Circuit pattern 12 is disposed on first main surface 11a of insulating layer 11 and includes a first portion (portion 14). Electrode 20 includes a second portion (portion 21) bonded to the first portion of circuit pattern 12. The bonding between the first portion of circuit pattern 12 and the second portion of electrode 20 is ultrasonic bonding. One of the first portion of circuit pattern 12 and the second portion of electrode 20 is fitted in the other of the first portion of circuit pattern 12 and the second portion of electrode 20.

Thus, in ultrasonic bonding between the first portion (portion 14) of circuit pattern 12 and the second portion (portion 21) of electrode 20, the movement of electrode 20 relative to circuit pattern 12 is restricted, so that misalignment of electrode 20 relative to circuit pattern 12 is suppressed. Furthermore, since the thickness of a part of insulating layer 11 is not reduced in order to suppress misalignment of electrode 20 relative to circuit pattern 12, the electrical insulation of insulating layer 11 is ensured.

In semiconductor apparatus 1 in the present embodiment, the first portion (portion 14) has recess 15. The second portion (portion 21) is fitted in recess 15.

Thus, misalignment of electrode 20 relative to circuit pattern 12 is suppressed, and the electrical insulation of insulating layer 11 is ensured.

In semiconductor apparatus 1 in the present embodiment, in a planar view of first main surface 11a of insulating layer 11, step 16 of recess 15 extends in a direction perpendicular to the direction of ultrasonic vibration applied for ultrasonic bonding between the first portion (portion 14) of circuit pattern 12 and the second portion (portion 21) of the electrode.

Misalignment of electrode 20 relative to circuit pattern 12 tends to occur in the direction of ultrasonic vibration applied for ultrasonic bonding between the first portion (portion 14) of circuit pattern 12 and the second portion (portion 21) of electrode 20. Step 16 of recess 15, however, extends in a direction perpendicular to the direction of ultrasonic vibration. Thus, step 16 restricts the movement of electrode 20. Misalignment of electrode 20 relative to circuit pattern 12 is suppressed more reliably by step 16 of recess 15.

In semiconductor apparatus 1 in the present embodiment, insulating layer 11 includes second main surface 11b opposite to first main surface 11a. Insulating substrate 10 includes heat dissipation plate 13 disposed on second main surface 11b of insulating layer 11.

Thus, heat generated in semiconductor apparatus 1 is efficiently dissipated to the outside of semiconductor apparatus 1 through heat dissipation plate 13.

The method of manufacturing semiconductor apparatus 1 in the present embodiment includes preparing insulating substrate 10 and electrode 20 (step S1). Insulating substrate 10 includes insulating layer 11 and circuit pattern 12. Circuit pattern 12 is disposed on insulating layer 11 and includes a first portion (portion 14). Electrode 20 includes a second portion (portion 21). The method of manufacturing semiconductor apparatus 1 in the present embodiment includes fitting one of the first portion of circuit pattern 12 and the second portion of electrode 20 into the other of the first portion of circuit pattern 12 and the second portion of electrode 20 (step S2), and ultrasonically bonding the first portion of circuit pattern 12 and the second portion of electrode 20 (step S3).

Thus, in the process of ultrasonically bonding the first portion (portion 14) of circuit pattern 12 and the second portion (portion 21) of electrode 20 (step S3), the movement of electrode 20 relative to circuit pattern 12 is restricted, so that misalignment of electrode 20 relative to circuit pattern 12 is suppressed. Furthermore, since the thickness of a part of insulating layer 11 is not reduced in order to suppress misalignment of electrode 20 relative to circuit pattern 12, the electrical insulation of insulating layer 11 is ensured.

### Second Embodiment

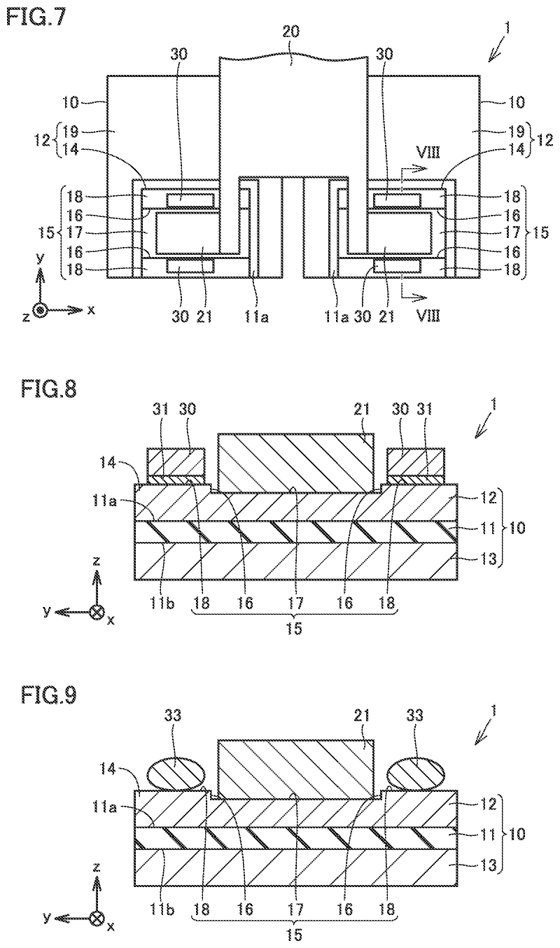

Referring to FIG. 7 and FIG. 8, semiconductor apparatus 1 according to a second embodiment will be described. Semiconductor apparatus 1 in the present embodiment has a configuration similar to that of semiconductor apparatus 1 in the first embodiment but differs mainly in the following points.

Semiconductor apparatus 1 in the present embodiment includes a metal block 30. Metal block 30 is formed of, for example, a metal such as Cu or Al. Metal block 30 is fixed to upper stepped surface 18 of recess 15, using a bonding member 31 such as solder or silver paste. In a planar view of first main surface 11a of insulating layer 11, metal block 30 is disposed along step 16 of recess 15.

Referring to FIG. 9, semiconductor apparatus 1 in a modification of the present embodiment further includes a wire 33. Wire 33 is formed of, for example, a metal such as Cu or Al. Wire 33 is fixed to upper stepped surface 18 of recess 15. For example, wire 33 is ultrasonically bonded to upper stepped surface 18 of recess 15. In a planar view of first main surface 11a of insulating layer 11, wire 33 is disposed along step 16 of recess 15.

Semiconductor apparatus 1 in the present embodiment achieves the following effects in addition to the effects of semiconductor apparatus 1 in the first embodiment.

Semiconductor apparatus 1 in the present embodiment further includes metal block 30 fixed to upper stepped surface 18 of recess 15. In a planar view of first main surface 11a of insulating layer 11, metal block 30 is disposed along step 16 of recess 15.

In ultrasonic bonding between the first portion (portion 14) of circuit pattern 12 and the second portion (portion 21) of electrode 20, not only recess 15 but also metal block 30 restricts the movement of electrode 20 relative to circuit pattern 12. Even when step 16 of recess 15 is small, misalignment of electrode 20 relative to circuit pattern 12 is suppressed in ultrasonic bonding between the first portion of circuit pattern 12 and the second portion of electrode 20.

Semiconductor apparatus 1 in the present embodiment further includes wire 33 fixed to upper stepped surface 18 of recess 15. In a planar view of first main surface 11a of insulating layer 11, wire 33 is disposed along step 16 of recess 15.

In ultrasonic bonding between the first portion (portion 14) of circuit pattern 12 and the second portion (portion 21) of electrode 20, not only recess 15 but also wire 33 restricts the movement of electrode 20 relative to circuit pattern 12. Even when step 16 of recess 15 is small, misalignment of electrode 20 relative to circuit pattern 12 is suppressed in ultrasonic bonding between the first portion of circuit pattern 12 and the second portion of electrode 20.

### Third Embodiment

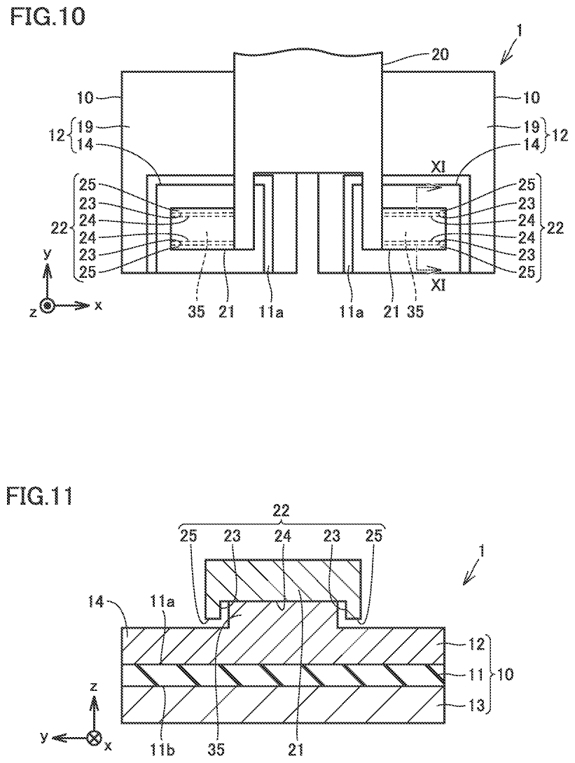

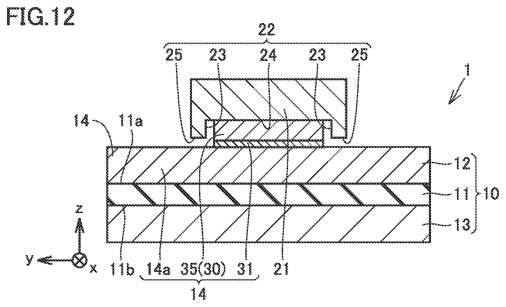

Referring to FIG. 10 and FIG. 11, semiconductor apparatus 1 according to a third embodiment will be described. Semiconductor apparatus 1 in the present embodiment has a configuration similar to that of semiconductor apparatus 1 in the first embodiment but differs mainly in the following points.

Portion 14 of circuit pattern 12 has a protrusion 35. Protrusion 35 is formed integrally with portion 14 of circuit pattern 12. Protrusion 35 is formed, for example, by etching with chemicals. Portion 21 of electrode 20 has a recess 22. Recess 22 is formed, for example, by stamping using a die. Protrusion 35 is fitted in recess 22.

Recess 22 includes a step 23, a lower stepped surface 24, and an upper stepped surface 25. Step 23 is connected to lower stepped surface 24 and upper stepped surface 25. In a planar view of first main surface 11a of insulating layer 11, a pair of steps 23 are opposed to both side surfaces of protrusion 35. Protrusion 35 is ultrasonically bonded to lower stepped surface 24 of recess 22. In a planar view of first main surface 11a of insulating layer 11, step 23 of recess 22 extends in a direction (for example, x direction) perpendicular to the direction (y direction) of ultrasonic vibration applied for ultrasonic bonding between portion 14 of circuit pattern 12 and portion 21 of the electrode.

The method of manufacturing semiconductor apparatus 1 in the present embodiment is similar to the method of manufacturing semiconductor apparatus 1 in the first embodiment shown in FIG. 5 and FIG. 6 but differs from the method of manufacturing semiconductor apparatus 1 in the first embodiment in the following points.

In the method of manufacturing semiconductor apparatus 1 in the present embodiment, in the process at step S1, insulating substrate 10 and electrode 20 are prepared. Insulating substrate 10 includes insulating layer 11 and circuit pattern 12. Circuit pattern 12 includes portions 14 and 19. Portion 14 of circuit pattern 12 has protrusion 35. Electrode 20 includes portion 21. Portion 21 of electrode 20 has recess 22.

In the method of manufacturing semiconductor apparatus 1 in the present embodiment, in the process at step S2, protrusion 35 provided at portion 14 of circuit pattern 12 is fitted into recess 22 provided in portion 21 of electrode 20.

In the method of manufacturing semiconductor apparatus 1 in the present embodiment, in the process at step S3, protrusion 35 provided at portion 14 of circuit pattern 12 is ultrasonically bonded to recess 22 provided in portion 21 of electrode 20. Specifically, protrusion 35 is ultrasonically bonded to lower stepped surface 24 of recess 22. Protrusion 35 is fitted in recess 22. A pair of steps 23 are opposed to both side surfaces of protrusion 35 to restrict the movement of electrode 20. Thus, during the ultrasonic bonding process (step S3), the movement of electrode 20 relative to circuit pattern 12 is restricted, so that misalignment of electrode 20 relative to circuit pattern 12 is suppressed. Furthermore, since the thickness of a part of insulating layer 11 is not reduced in order to suppress misalignment of electrode 20 relative to circuit pattern 12, the electrical insulation of insulating layer 11 is ensured.

Referring to FIG. 12, in semiconductor apparatus 1 in a modification of the present embodiment, portion 14 of circuit pattern 12 includes a conductive pattern 14a disposed on insulating layer 11, and a metal block 30. Conductive pattern 14a is formed of a metal such as copper (Cu) or aluminum (Al). Metal block 30 is fixed to conductive pattern 14a, using a bonding member 31 such as solder or silver paste. Metal block 30 is formed of, for example, a metal such as Cu or Al. Metal block 30 is protrusion 35.

Semiconductor apparatus 1 in the present embodiment achieves the following effects in addition to the effects of semiconductor apparatus 1 in the first embodiment.

In semiconductor apparatus 1 in the present embodiment, the first portion (portion 14) of circuit pattern 12 has protrusion 35. The second portion (portion 21) of the electrode has recess 22. Protrusion 35 is fitted in recess 22.

Thus, misalignment of electrode 20 relative to circuit pattern 12 is suppressed, and the electrical insulation of insulating layer 11 is ensured.

In semiconductor apparatus 1 in the present embodiment, protrusion 35 is formed integrally with the first portion (portion 14) of circuit pattern 12.

Thus, misalignment of electrode 20 relative to circuit pattern 12 is suppressed, and the electrical insulation of insulating layer 11 is ensured.

In semiconductor apparatus 1 in the present embodiment, the first portion (portion 14) of circuit pattern 12 includes conductive pattern 14a disposed on insulating layer 11, and metal block 30 fixed to conductive pattern 14a. Metal block 30 is protrusion 35.

Thus, misalignment of electrode 20 relative to circuit pattern 12 is suppressed, and the electrical insulation of insulating layer 11 is ensured.

In semiconductor apparatus 1 in the present embodiment, in a planar view of first main surface 11a of insulating layer 11, step 23 of recess 22 extends in a direction perpendicular to the direction of ultrasonic vibration applied for ultrasonic bonding between the first portion (portion 14) of circuit pattern 12 and the second portion (portion 21) of the electrode.

Misalignment of electrode 20 relative to circuit pattern 12 tends to occur in the direction of ultrasonic vibration applied for ultrasonic bonding between the first portion (portion 14) of circuit pattern 12 and the second portion (portion 21) of electrode 20. Step 23 of recess 22, however, extends in a direction perpendicular to the direction of ultrasonic vibration. Thus, step 23 of recess 22 restricts the movement of electrode 20. Misalignment of electrode 20 relative to circuit pattern 12 is suppressed more reliably by step 23 of recess 22.

Various aspects of the present disclosure will be summarized below as notes.

### Note 1

A semiconductor apparatus comprising:
an insulating substrate including an insulating layer including a first main surface, and a circuit pattern disposed on the first main surface and including a first portion; and
an electrode including a second portion bonded to the first portion, wherein
bonding between the first portion and the second portion is ultrasonic bonding, and
one of the first portion and the second portion is fitted in the other of the first portion and the second portion.

### Note 2

The semiconductor apparatus according to Note 1, wherein
the first portion has a recess, and
the second portion is fitted in the recess.

### Note 3

The semiconductor apparatus according to Note 2, wherein in a planar view of the first main surface, a step of the recess extends in a direction perpendicular to a direction of ultrasonic vibration applied for the ultrasonic bonding.

### Note 4

The semiconductor apparatus according to Note 2, further comprising a metal block fixed to an upper stepped surface of the recess,
wherein in a planar view of the first main surface, the metal block is disposed along a step of the recess.

### Note 5

The semiconductor apparatus according to Note 2, further comprising a wire fixed to an upper stepped surface of the recess,
wherein in a planar view of the first main surface, the wire is disposed along a step of the recess.

### Note 6

The semiconductor apparatus according to Note 1, wherein
the first portion has a protrusion,
the second portion has a recess, and
the protrusion is fitted in the recess.

### Note 7

The semiconductor apparatus according to Note 6, wherein the protrusion is formed integrally with the first portion.

### Note 8

The semiconductor apparatus according to Note 6, wherein
the first portion includes a conductive pattern disposed on the insulating layer, and a metal block fixed to the conductive pattern, and
the metal block is the protrusion.

### Note 9

The semiconductor apparatus according to any one of Notes 6 to 8, wherein in a planar view of the first main surface, a step of the recess extends in a direction perpendicular to a direction of ultrasonic vibration applied for the ultrasonic bonding.

### Note 10

The semiconductor apparatus according to any one of Notes 1 to 9, wherein
the insulating layer includes a second main surface opposite to the first main surface, and
the insulating substrate includes a heat dissipation plate disposed on the second main surface.

### Note 11

A method of manufacturing a semiconductor apparatus, comprising:
preparing an insulating substrate and an electrode, the insulating substrate including an insulating layer and a circuit pattern disposed on the insulating layer and including a first portion, the electrode including a second portion;
fitting one of the first portion and the second portion into the other of the first portion and the second portion; and
ultrasonically bonding the first portion and the second portion.

The first to third embodiments and modifications thereof disclosed here should be understood as being illustrative rather than being limitative in all respects. At least two of the first to third embodiments and modifications thereof disclosed here may be combined in a consistent manner. The scope of the present disclosure is shown not in the foregoing description but in the claims, and it is intended that all modifications that come within the meaning and range of equivalence to the claims are embraced here.

What is claimed is:

1. A semiconductor apparatus comprising:
an insulating substrate including an insulating layer including a first main surface, and a circuit pattern disposed on the first main surface and including a first portion; and
an electrode including a second portion bonded to the first portion, wherein
bonding between the first portion and the second portion is ultrasonic bonding, and
one of the first portion and the second portion is fitted in the other of the first portion and the second portion.

2. The semiconductor apparatus according to claim 1, wherein
the first portion has a recess, and
the second portion is fitted in the recess.

3. The semiconductor apparatus according to claim 2, wherein in a planar view of the first main surface, a step of the recess extends in a direction perpendicular to a direction of ultrasonic vibration applied for the ultrasonic bonding.

4. The semiconductor apparatus according to claim 2, further comprising a metal block fixed to an upper stepped surface of the recess,
wherein in a planar view of the first main surface, the metal block is disposed along a step of the recess.

5. The semiconductor apparatus according to claim 2, further comprising a wire fixed to an upper stepped surface of the recess,
wherein in a planar view of the first main surface, the wire is disposed along a step of the recess.

6. The semiconductor apparatus according to claim 1, wherein
the first portion has a protrusion,
the second portion has a recess, and
the protrusion is fitted in the recess.

7. The semiconductor apparatus according to claim 6, wherein the protrusion is formed integrally with the first portion.

8. The semiconductor apparatus according to claim 6, wherein
the first portion includes a conductive pattern disposed on the insulating layer, and a metal block fixed to the conductive pattern, and
the metal block is the protrusion.

9. The semiconductor apparatus according to claim 6, wherein in a planar view of the first main surface, a step of the recess extends in a direction perpendicular to a direction of ultrasonic vibration applied for the ultrasonic bonding.

10. The semiconductor apparatus according to claim 1, wherein
the insulating layer includes a second main surface opposite to the first main surface, and
the insulating substrate includes a heat dissipation plate disposed on the second main surface.

11. A method of manufacturing a semiconductor apparatus, comprising:
preparing an insulating substrate and an electrode, the insulating substrate including an insulating layer and a circuit pattern disposed on the insulating layer and including a first portion, the electrode including a second portion;
fitting one of the first portion and the second portion into the other of the first portion and the second portion; and
ultrasonically bonding the first portion and the second portion.
